(19) United States
(12) Patent Application Publication
(10) Pub. No.: US 2018/0108585 A1
(43) Pub. Date: Apr. 19, 2018

(54) CHIP PACKAGING STRUCTURE AND PACKAGING METHOD

(71) Applicant: China Wafer Level CSP Co., Ltd., Suzhou, Jiangsu (CN)

(72) Inventors: Zhiqi Wang, Suzhou, Jiangsu Province (CN); Ying Yang, Suzhou, Jiangsu Province (CN); Qiong Yu, Suzhou, Jiangsu Province (CN); Wei Wang, Suzhou, Jiangsu Province (CN)

(73) Assignee: China Wafer Level CSP Co., Ltd., Suzhou, Jiangsu (CN)

(21) Appl. No.: 15/573,679

(22) PCT Filed: Sep. 16, 2015
(86) PCT No.: PCT/CN2015/089700

§ 371 Date: Nov. 13, 2017

(30) Foreign Application Priority Data
May 19, 2015 (CN) 201510256904.5

(51) Int. Cl. H01L 23/31; G06F 3/044; H01L 23/00

(52) U.S. Cl. CPC H01L 23/31; H01L 2224/45144; H01L 24/05; G06F 3/044

(57) ABSTRACT

A chip package and packaging method are provided. The package includes: a substrate; a sensing chip coupled with the substrate, where the sensing chip has a first surface and a second surface opposite to the first surface and facing the substrate, where the sensing chip includes a sensing area arranged on the first surface and a peripheral area surrounding the sensing area, where the peripheral area is provided with a groove, and surfaces of sidewall and bottom of the groove and a surface of the peripheral area are provided with a rewiring layer, and the groove is exposed from sidewall of the sensing chip; and a plastic packaging layer arranged on the substrate, where the plastic packaging layer surrounds the sensing chip and fills the groove, and a surface of the sensing area is exposed from the plastic packaging layer.

### CROSS REFERENCE TO RELATED APPLICATION

This application claims priority to Chinese Patent Application No. 201510256904.5, titled “PACKAGE AND PACKAGING METHOD FOR FINGERPRINT IDENTIFICATION CHIP”, filed with the Chinese State Intellectual Property Office on May 19, 2015, which is incorporated herein by reference in its entirety.

### FIELD

The present disclosure relates to the technical field of semiconductor manufacturing, and particularly to a chip package and a chip packaging method.

### BACKGROUND

With the development of the modern society, the importance of personal identification and personal information security is brought into people's focus. Since one's fingerprint is unique and invariable, the fingerprint identification technology has the advantages of high security, good reliability and convenient use, which is widely used in various fields for protecting personal information security. With the development of science and technology, the problem of information security of various kinds of electronic products is always one of the key points. Especially for mobile terminal, such as a mobile phone, a laptop, a tablet computer, a digital camera, the demand for information security is more prominent.

Sensing method of a fingerprint identification device includes a capacitive type (an electric field type) method and an inductive type method. The fingerprint identification device extracts fingerprints of a user, converting the fingerprints of the user into an electrical signal, and outputting the electrical signal, in this way, fingerprint information of the user is acquired. Specifically, as shown in FIG. 1, FIG. 1 is a schematic cross-sectional structural diagram of a fingerprint identification device, the fingerprint identification device includes: a substrate 100, a fingerprint identification chip 101 coupled with a surface of the substrate 100 and a glass substrate 102 covering a surface of the fingerprint identification chip 101.

Taking a capacitive type fingerprint identification chip as an example, the fingerprint identification chip 101 includes one or more capacitance plates. Since the epidermis or hypodermis of a user finger has a raised ridge and a sunken valley, when a user finger 103 contacts a surface of the glass substrate 102, the distances from the ridge and the valley to the fingerprint identification chip 101 are different. Hence capacitance values between the ridge and the valley of a user finger 103 and a capacitance plate are different. The fingerprint identification chip 101 can acquire the different capacitance values, convert them into corresponding electrical signals, and output the electrical signals. After gathering all received electrical signals, the fingerprint identification device acquires fingerprint information of the user.

In an existing fingerprint identification device, high sensitivity of a fingerprint identification chip is required, thus limiting the manufacture and application of the fingerprint identification device.

### SUMMARY

A chip package and a chip packaging method are provided according to the embodiments of the disclosure to improve the sensitivity of a sensing chip.

In some embodiments of the present disclosure, a chip packaging method is provided. The chip packaging method includes:

providing a substrate;
coupling a sensing chip with the substrate, where the sensing chip has a first surface and a second surface opposite to the first surface, with the second surface of the sensing chip facing the substrate, where the sensing chip further includes a sensing area arranged on the first surface and a peripheral area surrounding the sensing area, where one or more grooves are formed in the peripheral area, and surfaces of a sidewall and a bottom of the groove and a surface of the peripheral area are provided with a rewiring layer, and the groove is exposed from a sidewall of the sensing chip; and
forming a plastic packaging layer on the substrate, where the plastic packaging layer surrounds the sensing chip and fills the groove, and a surface of the sensing area is exposed from the plastic packaging layer.

Optionally, forming the sensing chip includes:

providing a chip substrate, where the chip substrate includes multiple chip areas and cutting areas arranged between adjacent chip areas, where the chip substrate further has a first surface and a second surface opposite to each other, and each of the chip areas includes a sensing area arranged on the first surface of the chip substrate and a peripheral area surrounding the sensing area;
forming grooves in the cutting areas and the peripheral areas, where sidewalls of the grooves are arranged in the peripheral areas around the cutting areas;
forming a rewiring layer on surfaces of the peripheral areas and surfaces of the sidewalls and bottoms of the grooves; and
cutting the rewiring layer and the chip substrate in the cutting areas, to separate the multiple chip areas to form sensing chips.

Optionally, coupling the sensing chip with the surface of the substrate includes:

fixing the sensing chip to the surface of the substrate; and
connecting electrically the sensing chip with the substrate.

Optionally, the method further includes: forming a first contact pad at the bottom of the groove, where the first contact pad is electrically connected with the rewiring layer.

Optionally, the substrate has a first surface, the sensing chip is coupled with the first surface of the substrate, the first surface of the substrate is provided with a second contact pad.

Optionally, the method further includes: forming a conducting wire before the plastic packaging layer is formed, where two ends of the conducting wire are connected with the first contact pad and the second contact pad respectively, to electrically connect the sensing chip with the substrate.

Optionally, a point on the conducting wire having the greatest distance to the first surface of the substrate is served as a top point, and the top point is lower than the surface of the sensing area.

Optionally, the groove is a continuous groove surrounding the sensing area.

Optionally, the grooves include multiple discrete grooves surrounding the sensing area.

Optionally, the plastic packaging layer is formed in a fluid plastic packaging process.

Optionally, the plastic packaging layer is formed in a potting process.

Optionally, a surface of the plastic packaging layer is flush with the surface of the sensing area.

In some embodiments of the present disclosure, a chip package is also provided, the chip package includes:

a substrate;
a sensing chip coupled with the substrate, where the sensing chip has a first surface and a second surface opposite to the first surface, with the second surface of the sensing chip facing the substrate, where the sensing chip further includes a sensing area arranged on the first surface and a peripheral area surrounding the sensing area, where the peripheral area is provided with one or more grooves, and surfaces of a sidewall and a bottom of the groove and a surface of the peripheral area are provided with a rewiring layer, and the groove is exposed from a sidewall of the sensing chip; and
a plastic packaging layer arranged on the substrate, where the plastic packaging layer surrounds the sensing chip and fills the groove, and a surface of the sensing area is exposed from the plastic packaging layer.

Optionally, the chip package further includes a first contact pad arranged at the bottom of the groove, where the first contact pad is electrically connected with the rewiring layer.

Optionally, the substrate has a first surface, the sensing chip is coupled with the first surface of the substrate, the first surface of the substrate is provided with a second contact pad.

Optionally, the chip package further includes a conducting wire, where two ends of the conducting wire are electrically connected with the first contact pad and the second contact pad respectively, to electrically connect the sensing chip with the substrate.

Optionally, a point on the conducting wire having the greatest distance to the first surface of the substrate is served as a top point, and the top point is lower than the surface of the sensing area.

Optionally, the groove is a continuous groove surrounding the sensing area.

Optionally, the grooves include multiple discrete grooves surrounding the sensing area.

Optionally, a surface of the plastic packaging layer is flush with the surface of the sensing area.

### BRIEF DESCRIPTION OF THE DRAWINGS

FIG. 1 is a schematic cross-sectional structural diagram of a fingerprint identification device;

FIG. 2 is a schematic cross-sectional structural diagram of a fingerprint identification chip; and

FIG. 3 to FIG. 10 are schematic cross-sectional structural diagrams illustrating a forming procedure of a fingerprint identification chip according to the embodiments of the present disclosure.

### DETAILED DESCRIPTION OF EMBODIMENTS

As described in background part, a higher sensitivity of a fingerprint identification chip is required.

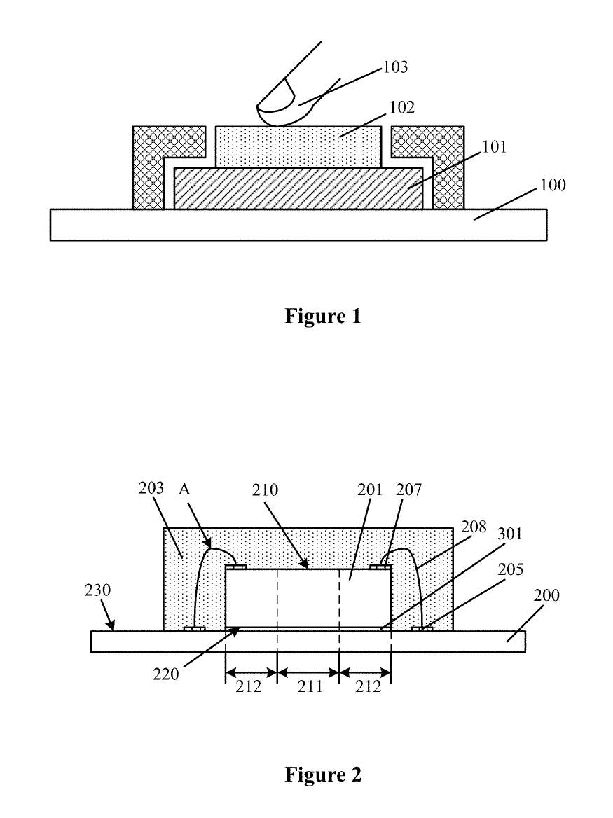

As shown in FIG. 1, a surface of a fingerprint identification chip 101 is covered with a glass substrate 102, the glass substrate 102 is configured to protect the fingerprint identification chip 101. A user finger 103 contacts the glass substrate 102 directly. Hence the glass substrate 102 has a greater thickness to ensure that the glass substrate 102 has enough protection capability. However, since the glass substrate 102 has a greater thickness, a higher sensitivity of the fingerprint identification chip 101 is required to guarantee that fingerprints of users are extracted accurately. Thus applications and promotion of the fingerprint identification chip are limited due to the great manufacturing difficulty and high manufacturing cost of the fingerprint identification chips with high sensitivity.

In order to decrease the requirement for sensitivity of the fingerprint identification chip, another fingerprint identification chip is provided, as show in FIG. 2. The fingerprint identification chip includes:

a substrate 200, where the substrate 200 has a first surface 230 provided with multiple first contact pads 205;
a sensing chip 201 arranged on the first surface 230 of the substrate 200, where the sensing chip 201 has a first surface 210 and a second surface 220 opposite to the first surface 210, the second surface 220 of the sensing chip 201 is arranged on the first surface 210 of the substrate 200, and the sensing chip 201 is also provided with a sensing area 211 arranged on the first surface 210 and a peripheral area 212 surrounding the sensing area 211, where a surface of the peripheral area 212 is provided with multiple second contact pads 207, and the locations of the second contact pads 207 correspond to the locations of the first contact pads 205 respectively, and the number of the second contact pads 207 equals to the number of the first contact pads 205;
multiple wires 208 with two ends electrically connecting to the first contact pad 205 and the second contact pad 207 respectively, where a point arranged on the wire 208 having the greatest distance to the first surface 210 of the substrate 200 is a top point A, and a distance from the top point to the first surface 210 of the sensing chip is served as a first distance; and a plastic packaging layer 203 arranged on surfaces of the substrate 200 and the sensing chip 201, where the plastic packaging layer 203 is made of polymer and the plastic packaging layer 203 surrounds the wires 208 and sensing chip 201, a surface of the plastic packaging layer 203 on the sensing area 201 is smooth, and a distance from the surface of the plastic packaging layer 203 to the first surface 210 of the sensing chip 201 is served as a second distance, which is greater than the first distance.

The conventional glass substrate is replaced by a plastic packaging layer on a surface of the sensing area 211, the plastic packaging layer is contacted with the user finger directly. By removing the glass substrate, sensing ability of the sensing chip 201 is improved. The sensing chip 201 is electrically connected with the substrate 200 through a wire 208, since the wire 208 have a top point A higher than the first surface 210 of the sensing chip 201, a second distance from a surface of the plastic packaging layer 203 to a first surface 210 of the sensing chip 201 should be greater than a first distance from the top point A of the wire 208 to a first surface 210 of the sensing chip 201 in order to make the plastic packaging layer 203 completely surround the wire 208. Therefore, the plastic packaging layer 203 arranged on the first surface 210 of the sensing chip 201 also has a great thickness. Additionally, the plastic packaging layer 203 covers the sensing area 211 of the sensing chip 201, thus the part of the plastic packaging layer 203 arranged on the sensing area 211 has a great thickness. Hence the plastic packaging layer 203 is also not good for improving the sensitivity of the sensing chip 201, and the sensing ability of a formed package is poor.

In order to attain the foregoing problems, a package and a packaging method for a fingerprint identification chip are provided in embodiments of the present disclosure. In the package, a sensing chip coupled with a surface of a substrate is provided with a groove in a peripheral area, where the peripheral area surrounds a sensing area. Surfaces of a sidewall and a bottom of the groove are provided with a rewiring layer electrically connected with the substrate, and the groove is exposed from the sidewall of the sensing chip. The plastic packaging layer surrounds and fixes the sensing chip, and fills the groove to protect the rewiring layer while the sensing area is exposed. Since the surface of the sensing area is not covered by the plastic packaging layer, a user finger can contact the sensing area directly, thereby using the sensing ability of the sensing chip to the greatest extent and improving the sensitivity of the sensing chip. Moreover, the thickness of a formed package can be decreased. Therefore, the formed package of the fingerprint identification chip has an increased sensitivity and a decreased size.

To better understand the foregoing objective, characteristics and advantages of the present disclosure, detailed descriptions of specific embodiments provided by the present disclosure are made in conjunction with the drawings hereinafter.

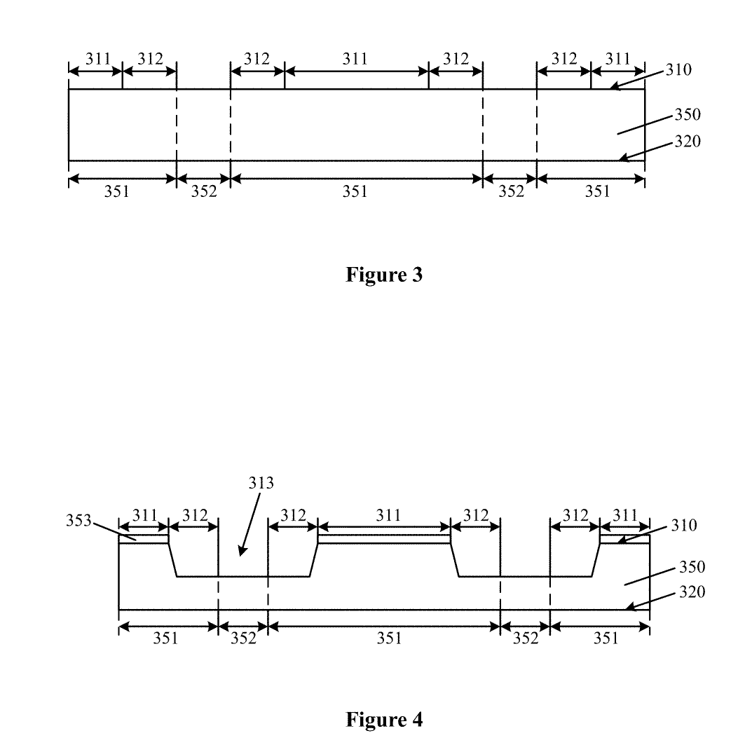

Reference are made to FIG. 3 to FIG. 10, which are schematic cross-sectional structural diagrams illustrating a packaging procedure of a fingerprint identification chip according to the embodiments of the present disclosure.

Referring to FIG. 3, a chip substrate 350 is provided. The chip substrate 350 includes multiple chip areas 351 and cutting areas 352 arranged between adjacent chip areas 351. The chip substrate 350 includes a first surface 310 and a second surface 320 opposite to each other. The chip area 351 includes a sensing area 311 arranged on the first surface 310 and a peripheral area 312 surrounding the sensing area 311.

The chip substrate 350 may be a silicon substrate, a silicon-germanium substrate, a silicon carbide substrate, a silicon-on-insulator (SOI) substrate, or a germanium-on-insulator (GOI) substrate, a silicon substrate, a silicon-germanium substrate, a silicon carbide substrate, a silicon-on-insulator (SOI) substrate, or a germanium-on-insulator (GOI) substrate; and the chip substrate 350 is a whole piece of wafer.

The chip area 351 is used to form a sensing chip (a fingerprint identification chip for example). By cutting the chip substrate 350 subsequently, multiple chip areas 351 are separated, to form independent sensing chips. In this embodiment, the chip areas 351 are arranged in an array, and a cutting area 352 is arranged between adjacent chip areas 351. By cutting the cutting areas 352, the chip areas 351 are separated from each other.

In this embodiment, a sensing device for acquiring fingerprint information of a user is formed in the sensing area 311. The sensing device includes a capacitance structure or an inductance structure, to make the sensing area 311 be able to detect and receive the fingerprint information of the user.

In addition, a chip circuit is formed in the sensing area 311 and the peripheral area 312 surrounding the sensing area 311. The chip circuit is electrically connected with the sensing device in the sensing area 311, to process electrical signals outputted by the sensing device.

In this embodiment, at least one capacitance plate is formed in the sensing area 311.

When a finger of a user contacts the surface of the sensing area 311, the capacitance plate and the finger of the user constitute a capacitance structure. And the sensing area 311 is able to acquire the difference of capacitance values from the ridge and valley on surface of the finger of the user to the capacitance plate, process the difference of capacitance values through a chip circuit and output the processed signal, in this way, fingerprint data of the user is acquired.

In this embodiment, since the sensing area 311 is exposed from a plastic packaging layer formed subsequently, the finger of the user can contact the surface of the sensing area 311 directly. To make sure that the finger of the user are isolated from the capacitance plate in the sensing area 311, a passivation layer is formed on the surface of the sensing area 311 of the sensing chip 301. The passivation layer is made of insulated material. The passivation layer is served as a dielectric layer between the finger of the user and the capacitance plate, to form a capacitance structure capable of acquiring fingerprint information of the user. And the passivation layer is also used to protect a chip circuit and a sensing device in the sensing area 311 from abrasion, and to electrically insulate the chip circuit and sensing device from external environments.

Referring to FIG. 4, a groove 313 is formed in the cutting area 352 and the peripheral area 312, and a sidewall of the groove 313 is arranged in the peripheral area 312 around the cutting area 352.

The formed groove 313 makes the surface of the peripheral area 312 lower than the surface of the sensing area 311. Thus after a sensing chip is formed by cutting the chip substrate 350 subsequently, when applying a plastic packaging layer to surround the sensing chip, the surface of the sensing area 311 is exposed when the plastic packaging layer covers the peripheral area. Thereby when the finger of the user contacts the sensing area 311, the peripheral area 312 is contacted. Thus not only the sensitivity of the sensing chip is improved, the thickness of a formed package is reduced, thereby reducing the size of the package.

Steps for forming the groove 313 include: forming a patterned photoresist layer 353 on the first surface 310 of the chip substrate 350, where the peripheral area 312 and the cutting area 352 are exposed from the photoresist layer 353; and etching the chip substrate 350 by using the photoresist layer 352 as a mask to form a groove 313 in the chip substrate 350. The photoresist layer 353 is formed by the coating process and lithography development process. The process of etching the chip substrate 350 is an anisotropic dry etching process.

In this embodiment, a sidewall of the formed groove 313 inclines with respect to the surface of the chip substrate 350, and an obtuse angle is formed between the sidewall of the groove 313 and the surface of the bottom. The bottom of the groove 313 is smaller than the top of the groove 313 in size. Since the sidewall of the groove 313 is inclined, it is better to form a rewiring layer on the surface of the sidewall of the groove, thus conveniently patterning the rewiring layer.

In an embodiment, the groove 313 is a continuous groove surrounding the sensing area 311, and one or more first contact pads are formed at the bottom of the continuous groove subsequently. In another embodiment, the grooves 313 include multiple discrete grooves surrounding the sensing area 311, and one or more first contact pads are formed at the bottom of each of the grooves 313 subsequently. A sensing chip formed by cutting is electrically connected with the substrate through the first contact pad.

The depth of the formed groove 313 should be greater than the distance from a top point on a conducting wire formed subsequently to the bottom of the groove 313, to avoid that the top point on the conducting wire formed subsequently is higher than the surface of the sensing area 311. It can be guarantee that a plastic packaging layer formed subsequently completely surrounds the conducting wire, and the surface of the plastic packaging layer is flush with the surface of the sensing area 311.

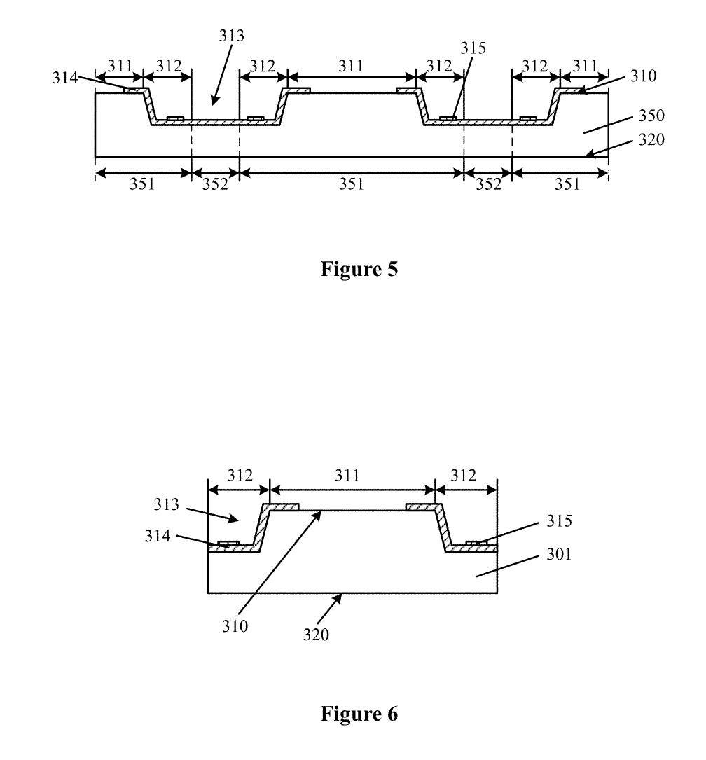

Referring to FIG. 5, a rewiring layer 314 is formed on a surface of the peripheral area 312 and surfaces of a sidewall and a bottom of the groove 313.

In this embodiment, after the rewiring layer 314 is formed, the photoresist layer 353 (as shown in FIG. 4) is removed. The process of removing the photoresist layer 353 is a wet stripping photoresist process or dry stripping photoresist process.

The rewiring layer 314 is electrically connected with the chip circuit, and is electrically connected with a substrate subsequently, such that a sensing device in the sensing area 311 and the chip circuit are electrically connected with the substrate.

The rewiring layer 314 is made of metal. Steps for forming the rewiring layer include: depositing a conductive layer on a first surface 310 of the chip substrate 350 and surfaces of the sidewall and the bottom of the groove 313; forming a patterned layer on a surface of the conductive layer, where the patterned layer defines a shape and location of the rewiring layer; and etching the conductive layer by taking the patterned layer as a mask, to form the rewiring layer. The patterned layer may be a patterned photoresist layer. The process of etching the conductive layer may be an anisotropic dry etching process or anisotropic wet etching process.

In this embodiment, the method further includes: forming a first contact pad 315 at the bottom of the groove 313, where the first contact pad 315 is electrically connected with the rewiring layer 314. As an out point of the rewiring layer, the first contact pad 315 may be electrically connected with a second contact pad on a surface of the substrate in the subsequent wire bonding process. The first contact pad is made of metal. The first contact pad may be formed after the rewiring layer 314 is formed, or at the same time when the rewiring layer 314 is formed.

The first contact pad 315 is formed at the bottom of the groove 313. And when one end of a conducting wire used in wire bonding subsequently is connected with the first contact pad 315, it may be ensured that the conducting wire is also arranged in the groove 313. Therefore a top point of the conducting wire is unlikely to be higher than a surface of the sensing area 311. When a plastic packaging layer is formed in the subsequent process, it can be ensured that the plastic packaging layer surrounds the conducting wire, and a surface of the plastic packaging layer is flush with a surface of the sensing area 311.

Referring to FIG. 6, the rewiring layer 314 and the chip substrate 350 (as shown in FIG. 5) are cut in the cutting area 352 (as shown in FIG. 5), to separate multiple chip areas 351 (as shown in FIG. 5) to form sensing chips 301.

The sensing chip 301 formed by cutting is coupled with a substrate provided subsequently to form a package.

The formed sensing chip 301 has a first surface 310 and a second surface 320 opposite to the first surface 310. The second surface 320 of the sensing chip 301 is arranged on a surface of a substrate provided subsequently. The sensing chip 301 includes a sensing area 311 arranged on the first surface 310 and a peripheral area 312 surrounding the sensing area 311. A groove 313 is formed in the peripheral area 312. A rewiring layer 314 is provided on surfaces of a sidewall and a bottom of the groove 313 and a surface of the peripheral area 312. The groove 313 is exposed from the sidewall of the sensing chip 301.

Since the cutting area 352 is provided with the groove 313, and the groove 313 extends to inside of the peripheral area 312 around the cutting area 352, after the cutting is performed in the cutting area 352, the bottom of the groove 313 is exposed from the sidewall of the formed sensing chip 301. Thus a surface of the peripheral area 312 of the formed sensing chip 301 is lower than a surface of the sensing area 311. When a conducting wire is connected with the peripheral area subsequently, a top point of the conducting wire is lower than a surface of the sensing area 311, so that the plastic packaging layer formed subsequently may completely cover the conducting wire.

A capacitance structure or an inductance structure for acquiring fingerprint information of the users is formed in the sensing area 311, so that the sensing area 311 can detect and receive fingerprint information of the user. A chip circuit and a sensing device are formed in the sensing area 311, and the chip circuit is electrically connected with the sensing device. The rewiring layer is electrically connected with the chip circuit, the chip circuit processes electrical signals outputted by the sensing device and the processed electrical signals are outputted through the rewiring layer 314.

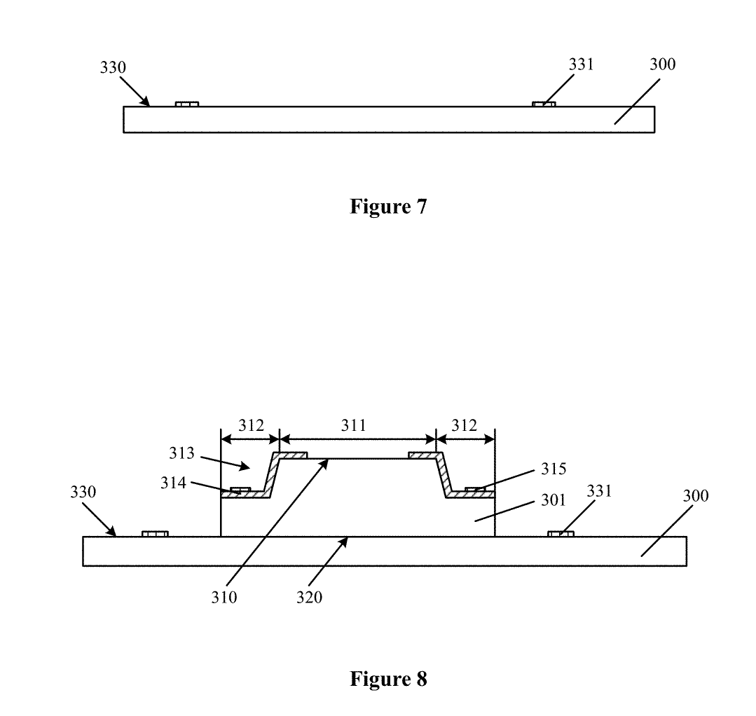

Referring to FIG. 7, a substrate 300 is provided.

The substrate 300 is a hard substrate or a soft substrate. In this embodiment, the substrate 300 is a hard substrate, for example, a PCB substrate, a glass substrate, a metal substrate, a semiconductor substrate or a polymer substrate.

In this embodiment, the substrate 300 has a first surface 330, and the first surface 330 of the substrate 300 is coupled with a sensing chip subsequently. The first surface 330 of the substrate 300 is provided with a wiring layer (not shown) and a second contact pad 331. The wiring layer is connected with the second contact pad 331, and the second contact pad 331 is electrically connected with a chip circuit on a surface of a sensing chip 301 (as shown in FIG. 7).

In an embodiment, a connection part is formed at one end of the substrate 300. The connection part is configured to electrically connect the sensing chip with an external circuit. The connection part is made of conductive material. The connection part is electrically connected with the wiring layer, such that a chip circuit on the sensing chip is electrically connected with an external circuit or device through the wiring layer on the third surface 330 of the substrate 300 and the connection part, to transmit electrical signals.

The sensing chip 301 is coupled with the surface of the substrate 300. Detailed descriptions for this process of coupling the sensing chip 301 with the surface of the substrate 300 are made in conjunction with drawings hereinafter.

Referring to FIG. 8, the sensing chip 301 is fixed on the surface of the substrate 300.

The sensing chip 301 and the substrate 300 are fixed to each other through a first adhesive layer. The surface of the first adhesive layer is provided with adhesive material.

In this embodiment, the first adhesive layer is adhered to the second surface 320 of the sensing chip 301. The first adhesive layer is adhered to the first surface 330 of the substrate 300, thus the sensing chip 301 is fixed to the first surface 330 of the substrate 300. The rewiring layer on the surface of the sensing chip 301 is electrically connected to the wiring layer on the surface of the substrate 300 through a subsequent wire bonding process, that is, the sensing chip 301 is coupled with the substrate 300.

In another embodiment, a first adhesive layer may be formed on the first surface 330 of the substrate 300. The sensing chip 301 is adhered to a surface of the first adhesive layer, and the sensing chip 301 is fixed to the surface of the substrate 300.

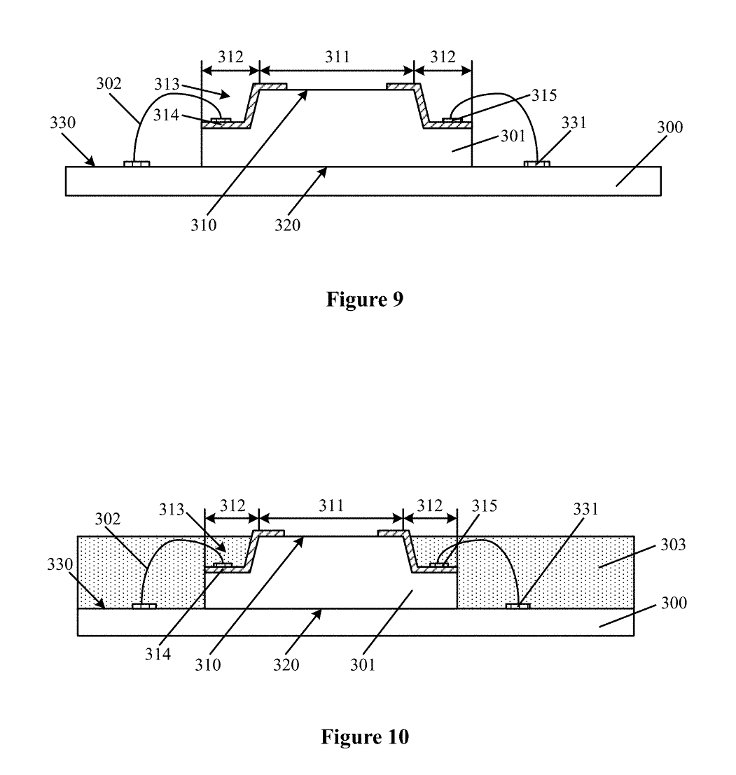

Referring to FIG. 9, the sensing chip 301 is electrically connected with the substrate 300.

The sensing chip 301 being electrically connected with the substrate 300 means that the sensing chip 301 being coupled with the substrate 300.

In this embodiment, a conducting wire 302 is formed by a wire bonding process. Two ends of the conducting wire 302 are connected with the first contact pad 315 and the second contact pad 331 respectively, so that the sensing chip 301 is electrically connected with the substrate 300. The conducting wire 302 causes the chip circuit to be electrically connected with the wiring layer on the surface of the substrate 300. And the wiring layer is electrically connected with the connection part. Electrical signals are transmitted between the chip circuit on the surface of the sensing chip 301, the sensing device and an external circuit or device. The conducting wire 302 is made of metal, which may be copper, tungsten, aluminum, gold or silver. The wire bonding process for realizing the electrical connection between the sensing chip 301 and the substrate 300 is simple and has a low cost.

The wire bonding process includes: providing a conducting wire 302; and connecting two ends of the conducting wire 302 with the first contact pad 315 and the second contact pad 331 by the welding process respectively. The conducting wire 302 is made of metal, which may be copper, tungsten, aluminum, gold or silver.

Since the conducting wire 302 is connected between the first contact pad 315 and the second contact pad 331, the conducting wire 302 is curved, and a point on the conducting wire 302 having the greatest distance to the first surface 330 of the substrate 300 is a top point. The top point is higher than a surface of the bottom of the groove 313, and is lower than the first surface 310 of the sensing chip 301. A surface of a plastic packaging layer formed subsequently is flush with the first surface 310 of the sensing chip 301, thus the top point is lower than the surface of the plastic packaging layer formed subsequently, and the plastic packaging layer formed subsequently can completely cover the conducting wire 302. Therefore the conducting wire 302 is electrically isolated from the sensing chip 301, and explosion of the conducting wire 302 is avoided.

Referring to FIG. 10, a plastic packaging layer 303 is formed on the surface of the substrate 300. The plastic packaging layer 303 surrounds the sensing chip 301 and fills the groove 313. And the surface of the sensing area 311 is exposed from the plastic packaging layer 303.

The plastic packaging layer 303 is used to protect and fix the substrate 300, the sensing chip 301 and the conducting wire 302, and to electrically isolate the conducting wire 302 from the sensing chip 301 or external environment.

In this embodiment, the peripheral area 312 of the sensing chip 301 is provided with the groove 313. The plastic packaging layer 303 fills the groove 313, and the surface of plastic packaging layer 303 is lower than or flush with the surface of the sensing area 311 of the sensing chip 301. Thus the plastic packaging layer can protect the rewiring layer 314, the first contact pad 315 and the conducting wire 302 arranged in the peripheral area 312.

In this embodiment, the top point of the conducting wire 302 is lower than the surface of the sensing area 311. The surface of the plastic packaging layer 303 is lower than or flush with the surface of the sensing area 311. Hence the plastic packaging layer 303 can completely surround the conducting wire 302.

In this embodiment, since the surface of the plastic packaging layer 303 is flush with the surface of the sensing area 311, the finger of the user can contact the surface of the sensing area 311 directly, thereby improving the sensitivity of the sensing chip. And since the surface of the plastic packaging layer 303 is flush with the surface of the sensing area 311, it is beneficial to reduce the thickness of the formed package, thereby reducing the size of the formed package.

The plastic packaging layer 303 is made of polymer material having characteristics of good flexibility, malleability and covering ability. The polymer material is epoxy resin, polyethylene, polypropylene, polyolefin, polyamide or polyurethane. The plastic packaging layer 303 may also be made of other suitable plastic packaging materials.

In this embodiment, the process of forming the plastic packaging layer 303 is a fluid plastic packaging process. In the fluid plastic packaging process, plastic packaging materials used for plastic packaging are provided, in the form of liquid state or flow state, to surfaces of the substrate 300 and the sensing chip 301. When the thickness of the plastic packaging material is higher than the top point of the conducting wire 302 and the surface of the sensing area 311 is exposed, solidification of the plastic packaging material is performed to form the plastic packaging layer 303. By using the fluid plastic packaging process, the thickness of the formed plastic packaging layer 303 is controlled strictly, to ensure that the plastic packaging layer 303 completely covers the conducting wire 302 and the surface of the plastic packaging layer 303 is lower than or flush with the surface of the sensing area 311 as well. The fluid plastic packaging process for the plastic packaging layer 303 includes a potting process.

In an embodiment, the process of forming the plastic packaging layer 303 is the potting process, including: potting low-viscosity plastic packaging materials to surfaces of the substrate 300 and the sensing chip 301 by using a liquid distributor; and heat curing is performed on the plastic packaging material when the thickness of the plastic packaging material reaches a preset thickness, to form a plastic packaging layer 303.

In an embodiment, the method further includes forming a protective ring on the surface of the substrate 300, the protective ring surrounds the sensing chip 301 and the plastic packaging layer 303. The protective ring is made of metal. The protective ring is grounded through the substrate 300, and is fixed to the first surface 330 of the substrate 300.

The protective ring is arranged around the sensing chip 301 and the plastic packaging layer 303. A part of the protective ring extends above the plastic packaging layer 303, and the surface of the sensing area 311 is exposed. In another embodiment, the protective ring is arranged around the sensing chip 301 and the plastic packaging layer 303 and surfaces of the plastic packaging layer 303 and the sensing area 311 are exposed.

The protective ring is made of metal, which may be copper, tungsten, aluminum, gold or silver. The protective ring is used to perform electrostatic protection on the sensing chip 301. When the finger of the user contacts the surface of the sensing area 311, static electricity is produced, since the protective ring is made of metal and is conductive, electrostatic charges are transmitted from the protective ring to the substrate 300 firstly, thus sensing devices in the sensing area 311 are prevented from breakdown by an overlarge static voltage, and the sensing chip 301 is protected, thereby improving the accuracy of fingerprint detection, eliminating signal noise outputted by the sensing chip 301, so that the sensing chip outputs more accurate signals.

In another embodiment, the method further includes: forming a housing surrounding the plastic packaging layer 303, the sensing chip 301 and the protective ring, where the surface of the sensing area 301 is exposed from the housing. The housing may be a housing for a device or a terminal that needs to be provided with a fingerprint identification chip, or may be a housing for a package of the fingerprint identification chip.

In another embodiment, the method may further include forming a housing surrounding the plastic packaging layer 303 and the sensing chip 301, the surface of the sensing area 311 is exposed from the housing.

In summary, in the embodiments, a sensing chip is provided with a groove in a peripheral area, the peripheral area surrounds a sensing area. Surfaces of a sidewall and a bottom of the groove are provided with a rewiring layer electrically connected with the substrate, and the groove is exposed from the sidewall of the sensing chip. A plastic packaging layer surrounding the sensing chip is formed on the surface of the substrate after the sensing chip is coupled with the surface of the substrate. The plastic packaging layer surrounds and fixes the sensing chip, and fills the groove to protect the rewiring layer while the sensing area is exposed. Since the surface of the sensing area is not covered by the plastic packaging layer, a user finger can contact the sensing area directly, thereby using the sensing ability of the sensing chip to the greatest extent and improving the sensitivity of the sensing chip. Therefore, the sensitivity of the formed package of the fingerprint identification chip is improved and the thickness of the formed package is decreased, and the size of the formed package is reduced.

Correspondingly, a package for a fingerprint identification chip formed according to the above method is also provided in embodiments of the present disclosure, as shown in FIG. 10. The package includes:

a substrate 300;
a sensing chip 301 coupled with a surface of the substrate 300, where the sensing chip 301 has a first surface 310 and a second surface 320 opposite to the first surface 310, with the second surface 320 of the sensing chip 301 facing the substrate 300, where the sensing chip 301 further includes a sensing area 311 arranged on the first surface 310 and a peripheral area 312 surrounding the sensing area 311, where the peripheral area 312 is provided with one or more grooves 313, and surfaces of a sidewall and a bottom of the groove 313 and a surface of the peripheral area 312 are provided with a rewiring layer 314, and the groove 313 is exposed from a sidewall of the sensing chip 301; and
a plastic packaging layer 303 arranged on the surface of the substrate 300, where the plastic packaging layer 303 surrounds the sensing chip 301 and fills the groove 313, and a surface of the sensing area 311 is exposed from the plastic packaging layer 303.

Descriptions of the above structure are made hereinafter.

In this embodiment, a sensing device for acquiring fingerprint information of a user is formed in the sensing area 311. The sensing device includes a capacitance structure or an inductance structure, to make the sensing area 311 be able to detect and receive the fingerprint information of the user.

In addition, a chip circuit is formed in the sensing area 311 and the peripheral area 312 surrounding the sensing area 311. The chip circuit is electrically connected with the sensing device in the sensing area 311, to process electrical signals outputted by the sensing device.

In this embodiment, at least one capacitance plate is formed in the sensing area 311. When a finger of a user contacts the surface of the sensing area 311, the capacitance plate and the finger of the user constitute a capacitance structure. And the sensing area 311 is able to acquire the difference of capacitance values from the ridge and valley on surface of the finger of the user to the capacitance plate, process the difference of capacitance values through a chip circuit and output the processed signal, in this way, fingerprint data of the user is acquired.

In this embodiment, a passivation layer is formed on the surface of the sensing area 311 of the sensing chip 301. The passivation layer is made of insulated material. The passivation layer is used to isolate the user figure from the capacitance plate in the sensing area 311. The passivation layer is served as a dielectric layer between the finger of the user and the capacitance plate, to form a capacitance structure capable of acquiring fingerprint information of the user. And the passivation layer is also used to protect a chip circuit and a sensing device in the sensing area 311 from abrasion, and to electrically insulate the chip circuit and sensing device from external environments.

The groove 313 makes the surface of the peripheral area 312 lower than the surface of the sensing area 311. When the plastic packaging layer 303 surrounds the sensing chip 301, the surface of the sensing area 311 is exposed when the plastic packaging layer 303 covers the peripheral area 312. Therefore, when the finger of the user contacts the sensing area 311, the peripheral area 312 is contacted. Thus not only the sensitivity of the sensing chip is improved, the thickness of a formed package is reduced, thereby reducing the size of the package.

In this embodiment, a sidewall of the groove 313 inclines with respect to the surface of the chip substrate 350, and an obtuse angle is formed between the sidewall of the groove 313 and the surface of the bottom. The bottom of the groove 313 is smaller than the top of the groove 313 in size.

In an embodiment, the groove 313 is a continuous groove surrounding the sensing area 311, and one or more first contact pads are formed at the bottom of the continuous groove.

In another embodiment, the grooves 313 include multiple discrete grooves surrounding the sensing area 311, and one or more first contact pads are formed at the bottom of each of the grooves 313. A sensing chip 301 is electrically connected with the substrate through the first contact pad.

The depth of the groove 313 should be greater than the distance from a top point on a conducting wire 302 to the bottom of the groove 313, to avoid that the top point on the conducting wire 302 is higher than the surface of the sensing area 311. It can be guarantee that a plastic packaging layer 303 completely surrounds the conducting wire 302, and the surface of the plastic packaging layer 303 is flush with the surface of the sensing area 311.

The rewiring layer 314 is electrically connected with the chip circuit, and is electrically connected with a substrate, such that a sensing device in the sensing area 311 and the chip circuit are electrically connected with the substrate.

In this embodiment, the package further includes a first contact pad 315 at the bottom of the groove 313, the first contact pad 315 is electrically connected with the rewiring layer 314.

The substrate 300 is a hard substrate or a soft substrate. In this embodiment, the substrate 300 is a hard substrate, for example, a PCB substrate, a glass substrate, a metal substrate, a semiconductor substrate or a polymer substrate.

The substrate 300 has a first surface 330, and the first surface 330 of the substrate 300 is coupled with a sensing chip. The first surface 330 of the substrate 300 is provided with a wiring layer (not shown) and a second contact pad 331. The wiring layer is connected with the second contact pad 331, and the second contact pad 331 is electrically connected with a chip circuit on a surface of a sensing chip 301.

In an embodiment, a connection part is formed at one end of the substrate 300. The connection part is configured to electrically connect the sensing chip 301 with an external circuit. The connection part is made of conductive material. The connection part is electrically connected with the wiring layer, such that a chip circuit on the sensing chip 301 is electrically connected with an external circuit or device through the wiring layer on the first surface 330 of the substrate 300 and the connection part, to transmit electrical signals.

The sensing chip 301 and the substrate 300 are fixed to each other through a first adhesive layer. The surface of the first adhesive layer is provided with adhesive material.

In this embodiment, the package further includes a conducting wire 302. Two ends of the conducting wire 302 are connected with the first contact pad 315 and the second contact pad 331 respectively, so that the sensing chip 301 is electrically connected with the substrate 300. The conducting wire 302 causes the chip circuit to be electrically connected with the wiring layer on the surface of the substrate 300. And the wiring layer is electrically connected with the connection part. Electrical signals are transmitted between the chip circuit on the surface of the sensing chip 301, the sensing device and an external circuit or device. The conducting wire 302 is made of metal, which may be copper, tungsten, aluminum, gold or silver.

The plastic packaging layer 303 is used to protect and fix the substrate 300, the sensing chip 301 and the conducting wire 302, and to electrically isolate the conducting wire 302 from the sensing chip 301 or external environment. The peripheral area 312 of the sensing chip 301 is provided with the groove 313. The plastic packaging layer 303 fills the groove 313, and the surface of plastic packaging layer 303 is lower than or flush with the surface of the sensing area 311 of the sensing chip 301. Thus the plastic packaging layer can protect the rewiring layer 314, the first contact pad 315 and the conducting wire 302 arranged in the peripheral area 312.

The plastic packaging layer 303 is made of polymer material having characteristics of good flexibility, malleability and covering ability. The polymer material is epoxy resin, polyethylene, polypropylene, polyolefin, polyamide or polyurethane. The plastic packaging layer 303 may also be made of other suitable plastic packaging materials.

In an embodiment, the package further includes a protective ring on the surface of the substrate 300, the protective ring surrounds the sensing chip 301 and the plastic packaging layer 303. The protective ring is made of metal. The protective ring is grounded through the substrate 300, and is fixed to the first surface 330 of the substrate 300.

In another embodiment, the package further includes a housing surrounding the plastic packaging layer 303, the sensing chip 301 and the protective ring, where the surface of the sensing area 301 is exposed from the housing. The housing may be a housing for a device or a terminal that needs to be provided with a fingerprint identification chip, or may be a housing for a package of the fingerprint identification chip.

In another embodiment, the package further includes a housing surrounding the plastic packaging layer 303 and the sensing chip 301, the surface of the sensing area 311 is exposed from the housing.

Compared with the conventional art, technical solutions of the present disclosure have advantages as follows.

In the method according to the disclosure, a sensing chip is provided with a groove in a peripheral area, the peripheral area surrounds a sensing area. Surfaces of a sidewall and a bottom of the groove are provided with a rewiring layer electrically connected with the substrate, and the groove is exposed from the sidewall of the sensing chip. A plastic packaging layer surrounding the sensing chip is formed on the surface of the substrate after the sensing chip is coupled with the surface of the substrate. The plastic packaging layer surrounds and fixes the sensing chip, and fills the groove to protect the rewiring layer while the sensing area is exposed. Since the surface of the sensing area is not covered by the plastic packaging layer, a user finger can contact the sensing area directly, thereby using the sensing ability of the sensing chip to the greatest extent and improving the sensitivity of the sensing chip. Therefore, the sensitivity of the formed package of the fingerprint identification chip is improved and the thickness of the formed package is decreased, and the size of the formed package is reduced.

Furthermore, in a process of forming the sensing chip, the sidewall of the groove is arranged in the peripheral area around the cutting area of the chip substrate, so the peripheral area of a formed sensing chip is provided with a groove after the chip substrate is cut in the cutting area. And the groove is exposed from the sidewall of the sensing chip, that is, a surface of the peripheral area is lower than a surface of the sensing area. Therefore, after a plastic packaging layer is formed, the peripheral area is covered by the plastic packaging layer while the sensing area is exposed from the plastic packaging layer. And surfaces of the sidewall and the bottom of the groove are provided with a rewiring layer, which is used to realize electrical connection between the formed sensing chip and the substrate after the chip substrate is cut.

Furthermore, the sensing chip is electrically connected with the substrate through a conducting wire. Two ends of the conducting wire are connected with the first contact pad on the peripheral area of the sensing chip and the second contact pad on the surface of the substrate respectively. Hence the conducting wire is curved. The conducting wire has a top point with the greatest distance to the first surface of the substrate. Since the peripheral area of the sensing chip is provided with the groove, and the surface of the peripheral area is lower than the surface of the sensing area, the top point is lower than the surface of the sensing area. After the plastic packaging layer fills the groove, the plastic packaging layer completely surrounds the conducting wire while the sensing area is exposed. Thereby a surface of the plastic packaging layer is flush with a surface of the sensing area, which is beneficial to reduce the thickness of a formed package, miniaturize the package, and improve the sensitivity of a sensing chip in the package.

In the package according to the disclosure, a sensing chip coupled with a surface of a substrate is provided with a groove in a peripheral area, the peripheral area surrounds a sensing area. Surfaces of a sidewall and a bottom of the groove are provided with a rewiring layer electrically connected with the substrate, and the groove is exposed from the sidewall of the sensing chip. A plastic packaging layer surrounds and fixes the sensing chip, and fills the groove to protect the rewiring layer while the sensing area is exposed. Since the surface of the sensing area is not covered by the plastic packaging layer, a user finger can contact the sensing area directly, thereby using the sensing ability of the sensing chip to the greatest extent and improving the sensitivity of the sensing chip. Therefore, the sensitivity of the package of the fingerprint identification chip is improved and the thickness of the package is decreased, and the size of the package is reduced.

In summary, in the embodiment, a sensing chip coupled with a surface of a substrate is provided with a groove in a peripheral area, the peripheral area surrounds a sensing area. Surfaces of a sidewall and a bottom of the groove are provided with a rewiring layer electrically connected with the substrate, and the groove is exposed from the sidewall of the sensing chip. A plastic packaging layer surrounds and fixes the sensing chip, and fills the groove to protect the rewiring layer while the sensing area is exposed. Since the surface of the sensing area is not covered by the plastic packaging layer, a user finger can contact the sensing area directly, thereby using the sensing ability of the sensing chip to the greatest extent and improving the sensitivity of the sensing chip. Therefore, the sensitivity of the package of the fingerprint identification chip is improved and the thickness of the package is decreased, and the size of the package is reduced.

The present disclosure is disclosed above, which is not limited thereto. Various alternations and modifications can be made to the technical solutions of the present disclosure by those skilled in the art without deviation from the spirit and scope of the present disclosure. Therefore, the protection scope of the present disclosure should be defined by the appended claims.

1. A chip package, comprising:
a substrate;
a sensing chip coupled with the substrate, wherein the sensing chip has a first surface and a second surface opposite to the first surface, with the second surface of the sensing chip facing the substrate, wherein the sensing chip further comprises a sensing area arranged on the first surface and a peripheral area surrounding the sensing area, wherein the peripheral area is provided with one or more grooves, and surfaces of a sidewall and a bottom of the groove and a surface of the peripheral area are provided with a rewiring layer, and the groove is exposed from a sidewall of the sensing chip; and
a plastic packaging layer arranged on the substrate, wherein the plastic packaging layer surrounds the sensing chip and fills the groove, and a surface of the sensing area is exposed from the plastic packaging layer.

2. The chip package according to claim 1, further comprising a first contact pad arranged at the bottom of the groove, wherein the first contact pad is electrically connected with the rewiring layer; wherein the substrate has a first surface, the sensing chip is coupled with the first surface of the substrate, the first surface of the substrate is provided with a second contact pad, and the first contact pad is electrically connected with the second contact pad.

3. The chip package according to claim 2, further comprising a conducting wire, wherein two ends of the conducting wire are electrically connected with the first contact pad and the second contact pad respectively.

4. The chip package according to claim 3, wherein a point on the conducting wire having the greatest distance to the first surface of the substrate is served as a top point, and the top point is lower than the surface of the sensing area.

5. The chip package according to claim 1, wherein the groove is a continuous groove surrounding the sensing area.

6. The chip package according to claim 1, wherein the grooves comprise a plurality of discrete grooves surrounding the sensing area.

7. The chip package according to claim 1, wherein a surface of the plastic packaging layer is flush with the surface of the sensing area.

8. The chip package according to claim 1, further comprising a passivation layer arranged on the surface of the sensing area of the sensing chip, wherein the passivation layer is made of insulating material.

9. A chip packaging method, comprising:
providing a substrate;
coupling a sensing chip with the substrate, wherein the sensing chip has a first surface and a second surface opposite to the first surface, with the second surface of the sensing chip facing the substrate, wherein the sensing chip further comprises a sensing area arranged on the first surface and a peripheral area surrounding the sensing area, wherein one or more grooves are formed in the peripheral area, and surfaces of a sidewall and a bottom of the groove and a surface of the peripheral area are provided with a rewiring layer, and the groove is exposed from a sidewall of the sensing chip; and
forming a plastic packaging layer on the substrate, wherein the plastic packaging layer surrounds the sensing chip and fill the groove, and a surface of the sensing area is exposed from the plastic packaging layer.

10. The chip packaging method according to claim 9, wherein forming the sensing chip comprises:
providing a chip substrate, wherein the chip substrate comprises a plurality of chip areas and cutting areas arranged between adjacent chip areas, wherein the chip substrate has a first surface and a second surface opposite to each other, and each of the chip areas comprises a sensing area arranged on the first surface of the chip substrate and a peripheral area surrounding the sensing area;
forming grooves in the cutting areas and the peripheral areas, wherein sidewalls of the grooves are arranged in the peripheral areas around the cutting areas;
forming a rewiring layer on surfaces of the peripheral areas and surfaces of the sidewalls and bottoms of the grooves; and
cutting the rewiring layer and the chip substrate in the cutting areas, to separate the plurality of chip areas to form sensing chips.

11. The chip packaging method according to claim 9, wherein the coupling a sensing chip with the substrate comprises:
fixing the sensing chip to the substrate; and
connecting electrically the sensing chip with the substrate.

12. The chip packaging method according to claim 9, further comprising:
forming a first contact pad at the bottom of the groove, wherein the first contact pad is electrically connected with the rewiring layer.

13. The chip packaging method according to claim 12, wherein the substrate has a first surface, the sensing chip is coupled with the first surface of the substrate, the first surface of the substrate is provided with a second contact pad, and the method further comprises:
forming a conducting structure to electrically connect the first contact pad with the second contact pad.

14. The chip packaging method according to claim 13, further comprising: forming a conducting wire before the plastic packaging layer is formed, wherein two ends of the conducting wire are electrically connected with the first contact pad and the second contact pad respectively.

15. The chip packaging method according to claim 14, wherein a point on the conducting wire having the greatest distance to the first surface of the substrate is served as a top point, and the top point is lower than the surface of the sensing area.

16. The chip packaging method according to claim 9, wherein a continuous groove surrounding the sensing area is formed.

17. The chip packaging method according to claim 9, wherein a plurality of discrete grooves surrounding the sensing area are formed.

18. The chip packaging method according to claim 9, further comprising: forming a passivation layer on the surface of the sensing area of the sensing chip.

19. The chip packaging method according to claim 9, wherein the plastic packaging layer is formed in a fluid plastic packaging process.

20. (canceled)

21. The chip packaging method according to claim 9, wherein a surface of the plastic packaging layer is flush with the surface of the sensing area.
